(19) United States
(12) Patent Application Publication
(10) Pub. No.: US 2026/0019071 A1
(43) Pub. Date: Jan. 15, 2026

(54) INDUCTIVE LOW-POWER WAKE-UP

(71) Applicant: SEMICONDUCTOR COMPONENTS INDUSTRIES, LLC, Scottsdale, AZ (US)

(72) Inventor: Jean-Paul Anna Joseph EGGERMONT, Pellaines (BE)

(73) Assignee: SEMICONDUCTOR COMPONENTS INDUSTRIES, LLC, Scottsdale, AZ (US)

(21) Appl. No.: 19/242,842

(22) Filed: Jun. 18, 2025

Related U.S. Application Data
(60) Provisional application No. 63/669,135, filed on Jul. 9, 2024.

(51) Int. Cl. H03K 5/24; G01B 7/30; H03K 17/56

(52) U.S. Cl. CPC H03K 5/24; G01B 7/30; H03K 17/56

(57) ABSTRACT

Wake-up systems and wake-up methods for an external power source and interfaces for angular position sensors. The system includes a rotatable sensor and an interface circuit. The rotatable sensor is configured to generate a plurality of phase signals. The interface circuit is configured to generate a first rectified signal by rectifying a first phase signal of the plurality of phase signals. The interface circuit is also configured to generate a first integrated signal by integrating the first rectified signal. The interface circuit is further configured to generate a wake-up signal for the external power source based on the first integrated signal.

### CROSS-REFERENCE TO RELATED APPLICATIONS

This application claims the benefit of U.S. Provisional Application No. 63/669,135 filed Jul. 9, 2024 and titled, “Inductive Low-Power Wake-Up.” The provisional application is incorporated by reference herein as if reproduced in full below.

### BACKGROUND

Many automotive and industrial applications enable main power when a rotor crosses a programmed position. For example, a brake pedal sensor in a vehicle may be used to activate brake power or main power when the brake pedal is pressed. As a further example, main power of a power tool may be activated when a contactless switch in the power tool detects that a trigger of the power tool is pressed. Further, many industrial applications that employ absolute encoders keep track of turn count even if main power is not supplied. For example, a turn count of a rotational sensor that determines how far a robotic arm has rotated may need to be tracked even if when the robot is powered down.

### SUMMARY

Employing always-active circuitry to monitor angular position in circumstances, such as the ones described above, reduces battery life. It is desirable to employ low-power circuitry to periodically monitor angular position. Thus, the present disclosure provides systems, methods, interfaces for operating angular position sensors that, among other things, integrate the phase signals generated by the angular position sensors.

The present disclosure provides a wake-up system for an external power source. The system includes, in one implementation, a rotatable sensor and an interface circuit. The rotatable sensor is configured to generate a plurality of phase signals. The interface circuit is configured to generate a first rectified signal by rectifying a first phase signal of the plurality of phase signals. The interface circuit is also configured to generate a first integrated signal by integrating the first rectified signal. The interface circuit is further configured to generate a wake-up signal for the external power source based on the first integrated signal.

The present disclosure also provides a wake-up method for an external power source. The method includes generating, with an angular position sensor, a plurality of phase signals in response to the excitation signal and based on a rotation of the angular position sensor. The method also includes generating a first rectified signal by rectifying a first phase signal of the plurality of phase signals. The method further includes generating a first integrated signal by integrating the first rectified signal. The method also includes generating a wake-up signal for the external power source based on the first integrated signal.

The present disclosure further provides an interface circuit for an angular position sensor. The interface circuit includes, in one implementation, a driver circuit and a signal processor. The driver circuit is configured to drive the angular position sensor to generate a plurality of phase signals. The signal processor includes a first terminal, a first rectifier, a first integrator, and a calculation circuit. The first terminal is configured to receive a first phase signal of the plurality of phase signals. The first rectifier is configured to generate a first rectified signal using the first phase signal. The first integrator is configured to generate a first integrated signal using the first rectified signal. The calculation circuit is configured to generate a wake-up signal for an external power source based on the first integrated signal.

### BRIEF DESCRIPTION OF THE DRAWINGS

For a detailed description of example implementations, reference will now be made to the accompanying drawings in which:

FIG. 1 is a partial schematic and a partial block diagram of an example of system for wake-up and turn count detection in accordance with some implementations;

FIG. 2 illustrates plots of examples of normalized waveforms of three phase signals for different angular positions of a sensor in accordance with some implementations;

FIG. 3 is a partial schematic and a partial block diagram of an example of a driver circuit in accordance with some implementations;

FIG. 4 illustrates plots of various signals included in the system of FIG. 1 in accordance with some implementations;

FIG. 5 is a partial schematic and a partial block diagram of an example of a signal processor in which phase signals are compared to a reference voltage in accordance with some implementations;

FIG. 6 is a partial schematic and a partial block diagram of an example of a signal processor in which phase signals are compared to each other in accordance with some implementations;

FIG. 7 is a partial schematic and a partial block diagram of an example of a signal processor in which a first phase signal is compared to a combination of a second phase signal and a third phase signal in accordance with some implementations;

FIG. 8 illustrates plots of examples of normalized waveforms of a first phase signal and different combinations of a second phase signal and a third phase signal for different angular positions of a sensor in accordance with some implementations;

FIG. 9 is schematic diagram of an example of a programmable resistor in accordance with some implementations; and

FIG. 10 is a flow diagram of an example of a method for wake-up detection in accordance with some implementations.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” in reference to a recited parameter shall mean the recited parameter plus or minus ten percent (+/−10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Controller” shall mean, alone or in combination, individual circuit components, an application specific integrated circuit (ASIC), a microcontroller with controlling software, a reduced-instruction-set computer (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Various examples are directed to systems, methods, interfaces for operating angular position sensors that, among other things, integrate the phase signals generated by the angular position sensors. More particularly, at least some examples are directed to interface circuits for angular position sensors that generate a wake-up signal or determine a turn count based on one or more integrated phase signals. Further, various examples are directed to low-power driver circuits that periodically generate excitation signals to drive angular position sensors. The specification now turns to an example system to orient the reader.

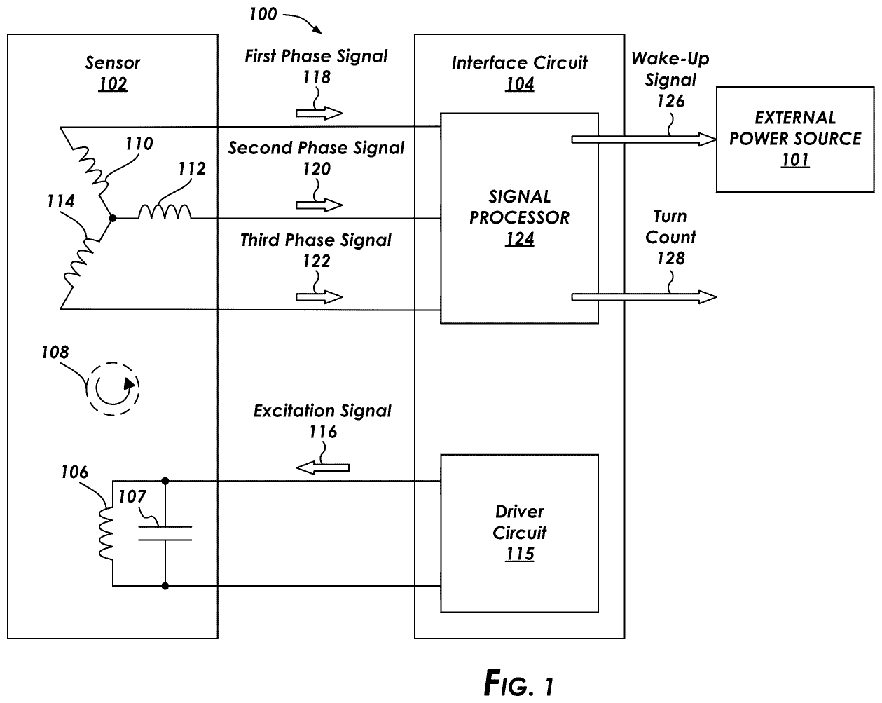

FIG. 1 is a partial schematic and a partial block diagram of an example of a wake-up system 100 for an external power source 101 and turn count detection in accordance with some implementations of the present disclosure. The wake-up system 100 illustrated in FIG. 1 includes a sensor 102 and an interface circuit 104. In some implementations, the wake-up system 100 may include more components, fewer components, or different components in different configurations than the wake-up system 100 illustrated in FIG. 1. In various implementations, the sensor 102 may include a multiphase inductive angular position sensor.

The sensor 102 illustrated in FIG. 1 (one example of a “rotatable sensor”) includes an excitation coil 106, a capacitor 107, a rotor coil 108, a first receiver coil 110, a second receiver coil 112, and a third receiver coil 114. The excitation coil 106 is fabricated (or “printed”) on a printed circuit board (PCB) (not shown). In various implementations, the excitation coil 106 is fabricated using copper or any other suitable material that can be printed on a PCB. The rotor coil 108 is fabricated from a conductive material and is configured to rotate above the PCB. In various implementations, the rotor coil 108 rotates in response to a change in rotational position of a specific object, for example, a pedal in a vehicle. The first receiver coil 110, the second receiver coil 112, and the third receiver coil 114 are also fabricated from a conductive material on the PCB. Although three receiver coils are depicted in the implementation of FIG. 1, in other implementations, any suitable number of receiver coils may be employed.

To measure rotation of the sensor 102, the interface circuit 104 includes a driver circuit 115 configured to generate an excitation signal 116 which is applied to the excitation coil 106 of the sensor 102. When the excitation signal 116 is applied to the excitation coil 106, a magnetic field is generated around the excitation coil 106. The magnetic field generated by the excitation coil 106 induces a current in the rotor coil 108, which, in turn, generates a magnetic field around the rotor coil 108. The magnetic field generated by the induced current in the rotor coil 108 couples into the first receiver coil 110, the second receiver coil 112, and the third receiver coil 114. The coupling from the rotor coil 108 to a given receiver coil is a function of both the distance between the rotor coil 108 and the given receiver coil, as well as the angular position of the rotor coil 108 and the given receiver coil. The magnetic field generated by the rotor coil 108 induces voltages in the first receiver coil 110 which causes the first receiver coil 110 to generate a first phase signal 118. The magnetic field generated by the rotor coil 108 also induces voltages in the second receiver coil 112 which causes the second receiver coil 112 to generate a second phase signal 120. The magnetic field generated by the rotor coil 108 further induces voltages in the third receiver coil 114 which causes the third receiver coil 114 to generate a third phase signal 122. The interface circuit 104 also includes a signal processor 124 that receives, among other things, the first phase signal 118, the second phase signal 120, and the third phase signal 122. As described below, the signal processor 124 is configured to generate a wake-up signal 126 using the first phase signal 118, the second phase signal 120, the third phase signal 122, or a combination thereof. The wake-up signal 126 activates the external power source 101. For example, the wake-up signal 126 can activate main power of a power tool when the sensor 102 is coupled to a contactless switch of the power tool. As a further example, the wake-up signal 126 can activate brake power or main power of a vehicle when the sensor 102 is coupled to a brake pedal of the vehicle. As an additional example, the wake-up signal 126 may activate a power source of a non-low-power system for angular position detection. As also described below, the signal processor 124 is configured to determine a turn count 128 using the first phase signal 118, the second phase signal 120, the third phase signal 122, or a combination thereof.

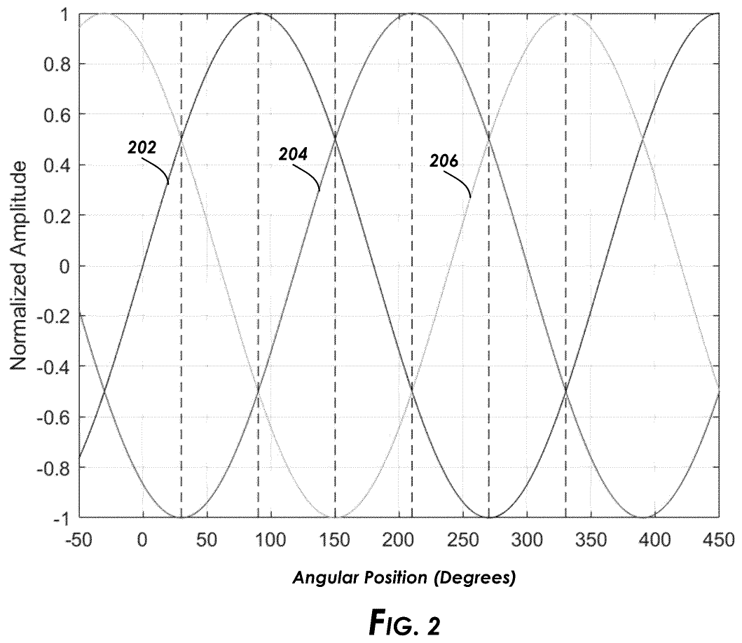

FIG. 2 illustrates plots of examples of waveforms 202, 204, and 206 of the first phase signal 118, the second phase signal 120, and the third phase signal 122, respectively, for different angular positions of the sensor 102. Each of the waveforms 202, 204, and 206 are offset from each other by sixty degrees. For example, waveform 202 crosses the zero-axis at 0° and 180°, waveform 204 crosses the zero-axis at 120° and 300°, and waveform 206 crosses the zero-axis at 60° and 240°. As illustrated in FIG. 2, the individual period of each of the waveforms 202, 204, and 206 covers one full rotation of the rotor coil 108.

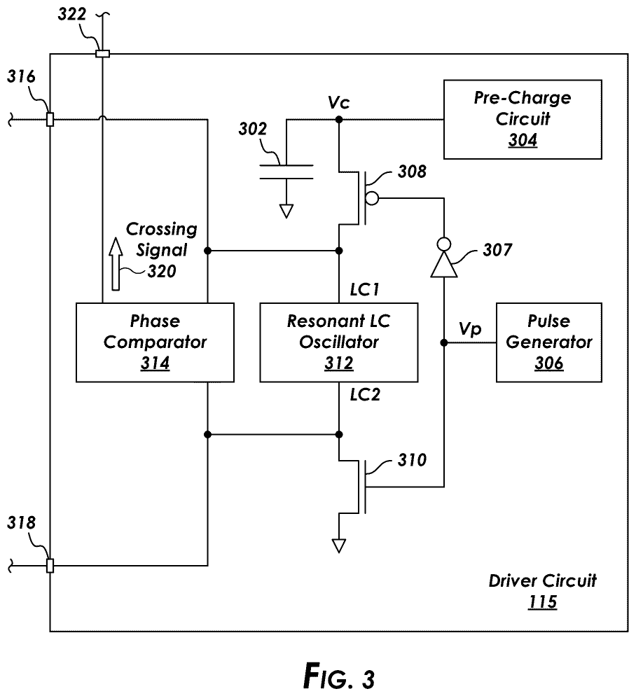

FIG. 3 is a partial schematic and a partial block diagram of an example of the driver circuit 115 in accordance with some implementations of the present disclosure. The driver circuit 115 illustrated in FIG. 3 includes a tank capacitor 302, a pre-charge circuit 304, a pulse generator 306, an inverter 307, a first transistor 308, a second transistor 310, a resonant LC oscillator 312, and a phase comparator 314. In some implementations, the driver circuit 115 may include more components, fewer components, or different components in different configurations than the driver circuit 115 illustrated in FIG. 3.

The driver circuit 115 periodically alternates between a power down mode and a power up mode. Prior to each wake-up, the tank capacitor 302 is charged to a predetermined supply voltage Vc by the pre-charge circuit 304. During each wake up, the pulse generator 306 generates an impulse signal Vp. The impulse signal Vp is inverted by the inverter 307. The inverted impulse signal briefly turns on the first transistor 308 and shorts a first terminal LC1 of the resonant LC oscillator 312 to the tank capacitor 302. Further, the impulse signal Vp briefly turns on the second transistor 310 and shorts a second terminal LC2 of the resonant LC oscillator 312 to a reference (or ground) terminal. Briefly shorting the first terminal LC1 and the second terminal LC2 of the resonant LC oscillator 312 as described above causes the resonant LC oscillator 312 to generate the excitation signal 116. The first terminal LC1 and the second terminal LC2 of the resonant LC oscillator 312 are coupled to a first terminal 316 and a second terminal 318 of the driver circuit 115, respectively, to provide the excitation signal 116 to the excitation coil 106 of the sensor 102.

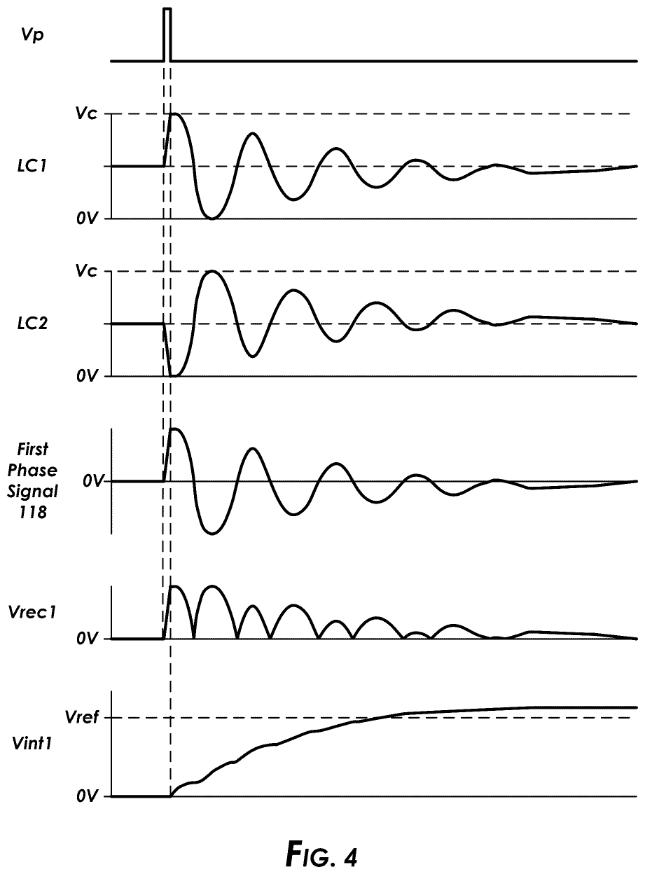

FIG. 4 illustrates a plot of an example of the impulse signal Vp. Further, FIG. 4 illustrates plots of examples of dumped oscillation signals formed at the first terminal LC1 and the second terminal LC2 of the resonant LC oscillator 312 in response to the impulse signal Vp. As illustrated in FIG. 4, the dumped oscillation signals at the first terminal LC1 and the second terminal LC2 of the resonant LC oscillator 312 oscillate between the supply voltage Vc and about zero volts. FIG. 4 further illustrates a plot of an example of the first phase signal 118 generated by the first receiver coil 110 in response to the excitation signal 116.

As described below, the signal processor 124 rectifies the first phase signal 118, the second phase signal 120, and the third phase signal 122. Returning to FIG. 3, to enable rectification, the phase comparator 314 is configured to generate a crossing signal 320 that indicates when the signals at the first terminal LC1 and the second terminal LC2 of the resonant LC oscillator 312 cross each other. The phase comparator 314 is coupled to a third terminal 322 of the driver circuit 115 to provide the crossing signal 320 to the signal processor 124.

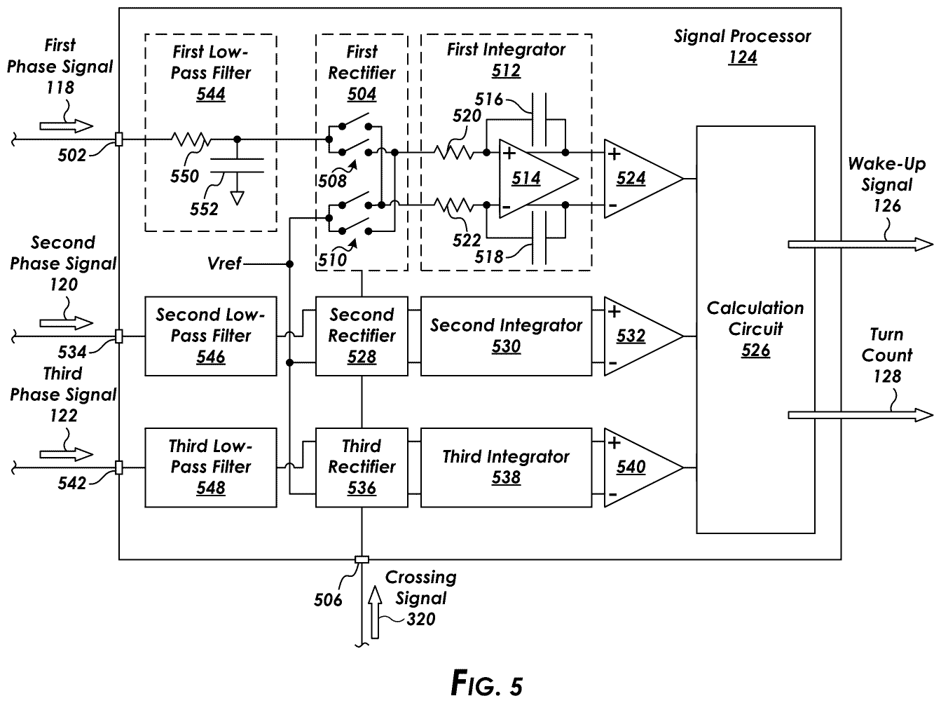

FIG. 5 is a partial schematic and a partial block diagram of an example of the signal processor 124 in accordance with some implementations of the present disclosure. The first phase signal 118 is received at a first terminal 502 of the signal processor 124. As illustrated in FIG. 4, the first phase signal 118 oscillates about the zero-axis. Thus, the signal processor 124 includes a first rectifier 504 configured to generate a first rectified signal Vrec1 by rectifying the first phase signal 118. The first rectifier 504 generates the first rectified signal Vrec1 using the crossing signal 320. The first rectifier 504 receives the crossing signal 320 from a control terminal 506 of the signal processor 124 that is coupled to the driver circuit 115. In FIG. 5, the first rectifier 504 includes a first pair of switches 508 and a second pair of switches 510. The first pair of switches 508 routs the first phase signal 118 to one of the two outputs of the first rectifier 504 based on the crossing signal 320. For example, the first pair of switches 508 may route the first phase signal 118 to a first of the two outputs when the crossing signal 320 indicates a first crossing of the signals at the first terminal LC1 and the second terminal LC2 of the resonant LC oscillator 312, and then route the first phase signal 118 to a second of the two outputs when the crossing signal 320 indicates a second crossing of the signals at the first terminal LC1 and the second terminal LC2 of the resonant LC oscillator 312. The second pair of switches 510 routs a reference voltage Vref to one of the two outputs of the first rectifier 504 based on the crossing signal 320. In particular, the second pair of switches 510 routs the reference voltage Vref to the output opposite the one which the first phase signal 118 is currently routed to.

Returning to FIG. 4, FIG. 4 illustrates a plot of an example of the first rectified signal Vrec1. When the polarity of the first rectified signal Vrec1 is positive (as illustrated in FIG. 4), the angular position of the sensor 102 is between 0° and 180°. Alternatively, when the polarity of the first rectified signal Vrec1 is negative, the angular position of the sensor 102 is between 180° and 360°. Thus, determination of the angular position of the sensor 102 can be narrowed by a hundred and eighty degrees by determining the polarity of the first rectified signal Vrec1. However, as illustrated in FIG. 4, the first rectified signal Vrec1 returns to about zero volts each time the signals at the first terminal LC1 and the second terminal LC2 of the resonant LC oscillator 312 cross the zero-axis. Thus, comparing the first rectified signal Vrec1 to a reference voltage Vref of, e.g., zero volts, may not accurately determine the polarity of the first rectified signal Vrec1 because the first rectified signal Vrec1 may alternate between being above and below the reference voltage Vref.

Returning to FIG. 5, the signal processor 124 includes a first integrator 512 configured to generate a first integrated signal Vint1 by integrating the first rectified signal Vrec1. In FIG. 5, the first integrator 512 includes an operational transconductance amplifier 514, a first capacitor 516, a second capacitor 518, a first resistor 520, and a second resistor 522. The first capacitor 516 is coupled between a first output and a non-inverting input of the operational transconductance amplifier 514. The second capacitor 518 is coupled between a second output and an inverting input of the operational transconductance amplifier 514. The first resistor 520 is coupled in series with the non-inverting input of the operational transconductance amplifier 514. The second resistor 522 is coupled in series with the inverting input of the operational transconductance amplifier 514. The operational transconductance amplifier 514 generates and outputs the first integrated signal Vint1 on one of its two outputs. The operational transconductance amplifier 514 also outputs the reference voltage Vref on the other of its two outputs.

Returning to FIG. 4, FIG. 4 illustrates a plot of an example of the first integrated signal Vint1. Similar to the first rectified signal Vrec1, when the polarity of the first integrated signal Vint1 is positive (as illustrated in FIG. 4), the angular position of the sensor 102 is between 0° and 180°. Alternatively, when the polarity of the first integrated signal Vint is negative, the angular position of the sensor 102 is between 180° and 360°. As illustrated in FIG. 4, the polarity of the first integrated signal Vint1 is constant. Thus, comparing the first integrated signal Vint1 to a reference voltage Vref of, e.g., zero volts, provides an accurate determination of the polarity of the first rectified signal Vrec1. Further, integrating the first rectified signal Vrec1 can increase detection accuracy by removing unwanted noise from the phase signals.

Returning to FIG. 5, the signal processor 124 includes a first comparator 524 configured to generate a first comparison signal Vcomp1 by comparing the first integrated signal Vint1 and the reference voltage Vref. The first comparison signal Vcomp1 indicates the polarity of the first integrated signal Vint1. For example, when the first integrated signal Vint1 is greater than the reference voltage Vref, the first comparison signal Vcomp1 may be set to a first value (e.g., a positive value) indicating a positive polarity for the first integrated signal Vint1. Further, when the first integrated signal Vint1 is less than the reference voltage Vref, the first comparison signal Vcomp1 may be set to a second value (e.g., a negative value) indicating a negative polarity for the first integrated signal Vint1.

The first comparison signal Vcomp1 is received by a calculation circuit 526 of the signal processor 124. The calculation circuit 526 is configured to generate the wake-up signal 126 and determine the turn count 128. To accomplish this, the calculation circuit 526 may determine the angular position of the sensor 102. As described above, the angular position of the sensor 102 is between 0° and 180° when the polarity of the first integrated signal Vint1 is positive. Further, the angular position of the sensor 102 is between 180° and 360° when the polarity of the first integrated signal Vint1 is negative. Thus, the calculation circuit 526 can use the first comparison signal Vcomp1 to narrow the determination of the angular position of the sensor 102 by a hundred and eighty degrees.

In some implementations, the calculation circuit 526 is configured to generate the wake-up signal 126 using the first comparison signal Vcomp1. For example, when the sensor 102 rotates away from a default position of −10° to a position of 10°, the calculation circuit 526 detects a change in polarity of the first comparison signal Vcomp1 and can pulse the wake-up signal 126.

In some implementations, the reference voltage Vref may be about zero volts. Alternatively, the reference voltage Vref greater than or less than zero volts. For example, the reference voltage Vref may be slightly greater than the zero volts to ensure that the first comparison signal Vcomp1 accurately indicates a change from negative polarity to positive polarity. Further, when the sensor 102 has a default position around 0°, the reference voltage Vref may be slightly greater than the zero volts to ensure rotation of the sensor 102 away from the default position triggers a change in the first comparison signal Vcomp1 that can be used for wake-up detection.

In some implementations, to provide a more precise determination of the angular position of the sensor 102, the signal processor 124 is configured to determine the polarities of other phase signals. For example, the signal processor 124 in FIG. 5 includes a second rectifier 528, a second integrator 530, and a second comparator 532 that collectively generate a second comparison signal Vcomp2 for the second phase signal 120 (which is received at a second terminal 534 of the signal processor 124). Further, the signal processor 124 in FIG. 5 includes a third rectifier 536, a third integrator 538, and a third comparator 540 that collectively generate a third comparison signal Vcomp3. The second rectifier 528 and the third rectifier 536 may rectify the second phase signal 120 and the third phase signal 122, respectively, using the crossing signal 320. In some implementations, the second rectifier 528 and the third rectifier 536 includes components similar to the ones described above for the first rectifier 504. Further, the second integrator 530 and the third integrator 538 may include components similar to the ones described above for the first integrator 512.

Returning to FIG. 2, the angular position of the sensor 102 is between 120° and 300° when the polarity of the waveform 204 (which is associated with the second phase signal 120) is positive, and the angular position of the sensor 102 is between 0° and 120° or between 300° and 360° when the polarity of waveform 204 is negative. Further, the angular position of the sensor 102 is between 0° and 60° or between 240° and 360° when the polarity of the waveform 206 (which is associated with the third phase signal 122) is positive, and the angular position of the sensor 102 is between 60° and 240° when the polarity of waveform 206 is negative. Thus, the calculation circuit 526 can use the first comparison signal Vcomp1, the second comparison signal Vcomp2, and the third comparison signal Vcomp3 to narrow the determination of the angular position of the sensor 102 to within sixty degrees. For example, with reference to waveforms 202, 204, and 206 in FIG. 2, the calculation circuit 526 in FIG. 5 can determine that the angular position of the sensor 102 is between 0° and 60° when the first comparison signal Vcomp1 indicates a positive polarity, the second comparison signal Vcomp2 indicates a negative polarity, and the third comparison signal Vcomp3 indicates a positive polarity. As a further example, the calculation circuit 526 in FIG. 5 can determine that the angular position of the sensor 102 is between 60° and 120° when the first comparison signal Vcomp1 indicates a positive polarity, the second comparison signal Vcomp2 indicates a negative polarity, and the third comparison signal Vcomp3 indicates a negative polarity.

The calculation circuit 526 can determine the turn count 128 using the first comparison signal Vcomp1, the second comparison signal Vcomp2, the third comparison signal Vcomp3, or a combination thereof. In some implementations, the calculation circuit 526 using a combination of the first comparison signal Vcomp1, the second comparison signal Vcomp2, and the third comparison signal Vcomp3 to determine each time the sensor 102 rotates past a set angular position. For example, when the set angular position is 120°, the calculation circuit 526 can increment the turn count by one upon detecting the second comparison signal Vcomp2 changing from negative polarity to positive polarity (indicating rotation of the sensor 102 from a position below 120° to a position above 120°) after detecting the third comparison signal Vcomp3 changing from positive polarity to negative polarity (indicating rotation of the sensor 102 from a position below 60° to a position above 60°).

In some implementations, the signal processor 124 may filter the first phase signal 118, the second phase signal 120, and the third phase signal 122 prior to rectification. For example, automotive applications of the wake-up system 100 may require electromagnetic compatibility (EMC) filtering of the phase signals upon entering the signal processor 124. In some implementations, EMC filtering may be provided by low-pass filters, such as a 30 MHz low-pass filter. For example, in FIG. 5, the signal processor 124 includes a first low-pass filter 544 between the first terminal 502 and the first rectifier 504, a second low-pass filter 546 between the second terminal 534 and the second rectifier 528, and a third low-pass filter 548 between the third terminal 542 and the third rectifier 536. The first low-pass filter 544 is configured to generate a first filtered phase signal by low-pass filtering the first phase signal 118. In FIG. 5, the first low-pass filter 544 is an RC filter formed by a resistor 550 and a capacitor 552. In some implementations, the second low-pass filter 546 and the third low-pass filter 548 include components similar to the ones described above for the first low-pass filter 544. In some implementations, the first low-pass filter 544, the second low-pass filter 546, and the third low-pass filter 548 may be formed by other types of passive low-pass filters.

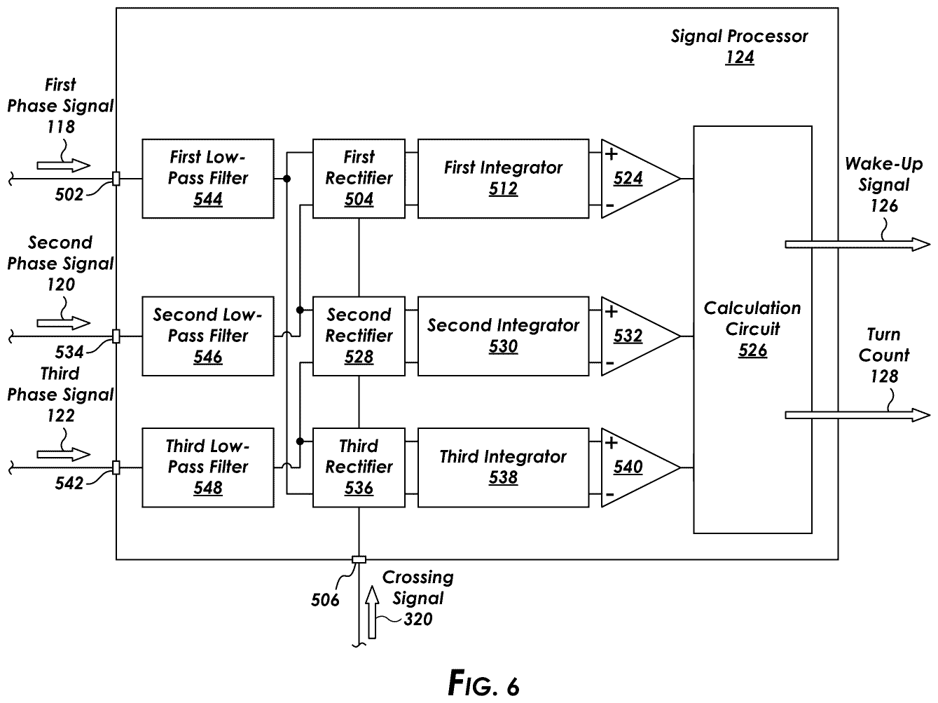

FIG. 6 is a partial schematic and a partial block diagram of an example of the signal processor 124 in which the first phase signal 118, the second phase signal 120, and the third phase signal 122 are compared to each other. The first phase signal 118 and the second phase signal 120 are fed into the first rectifier 504 in FIG. 6, and the first comparator 524 in FIG. 6 generates a first comparison signal Vcomp1 that indicates whether the first phase signal 118 is greater than or less than the second phase signal 120. For example, the first comparison signal Vcomp1 may be a first value (e.g., a positive value) when the first phase signal 118 is greater than the second phase signal 120, and the first comparison signal Vcomp1 may be a second value (e.g., a negative value) when the first phase signal 118 is less than the second phase signal 120.

Further, the second phase signal 120 and the third phase signal 122 are fed into the second rectifier 528 in FIG. 6, and the second comparator 532 in FIG. 6 generates a second comparison signal Vcomp2 that indicates whether the second phase signal 120 is greater than or less than the third phase signal 122. For example, the second comparison signal Vcomp2 may be a first value when the second phase signal 120 is greater than the third phase signal 122, and the second comparison signal Vcomp2 may be a second value when the second phase signal 120 is less than the third phase signal 122. Also, the first phase signal 118 and the third phase signal 122 are fed into the third rectifier 536 in FIG. 6, and the third comparator 540 in FIG. 6 generates a third comparison signal Vcomp3 that indicates whether the first phase signal 118 is greater than or less than the third phase signal 122. For example, the third comparison signal Vcomp3 may be a first value when the first phase signal 118 is greater than the third phase signal 122, and the third comparison signal Vcomp3 may be a second value when the first phase signal 118 is less than the third phase signal 122.

Returning to FIG. 2, the angular position of the sensor 102 is between 0° and 150° or between 330° and 360° when waveform 202 (which is associated with the first phase signal 118) is greater than waveform 204 (which is associated with the second phase signal 120), and the angular position of the sensor 102 is between 150° and 330° when waveform 202 is less than waveform 204. Further, the angular position of the sensor 102 is between 90° and 270° when waveform 204 is greater than waveform 206 (which is associated with the third phase signal 122), and the angular position of the sensor 102 is between 0° and 90° or between 270° and 360° when waveform 204 is less than waveform 206. In addition, the angular position of the sensor 102 is between 30° and 210° when waveform 202 is greater than waveform 206, and the angular position of the sensor 102 is between 0° and 30° or between 210° and 360° when waveform 204 is less than waveform 206. Thus, the calculation circuit 526 in FIG. 6 can use the first comparison signal Vcomp1, the second comparison signal Vcomp1, and the third comparison signal Vcomp3 to narrow the determination of the angular position of the sensor 102 to within sixty degrees. For example, with reference to waveforms 202, 204, and 206 in FIG. 2, the calculation circuit 526 in FIG. 6 can determine that the angular position of the sensor 102 is between 30° and 90° when the first comparison signal Vcomp1 indicates that waveform 202 is greater than waveform 204, the second comparison signal Vcomp2 indicates that waveform 204 is less than waveform 206, and the third comparison signal Vcomp3 indicates that waveform 202 is greater than waveform 206. As a further example, the calculation circuit 526 in FIG. 6 can determine that the angular position of the sensor 102 is between 90° and 150° when the first comparison signal Vcomp1 indicates that waveform 202 is greater than waveform 204, the second comparison signal Vcomp2 indicates that waveform 204 is greater than waveform 206, and the third comparison signal Vcomp3 indicates that waveform 202 is greater than waveform 206.

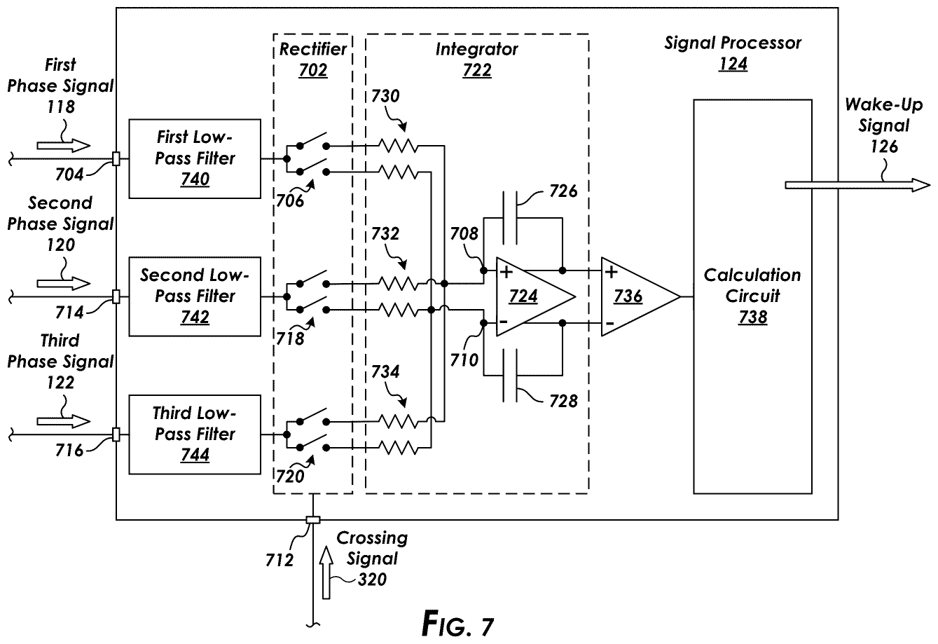

To increase the resolution of angular position detection, the first phase signal 118 can be compared to a combination of the second phase signal 120 and the third phase signal 122. FIG. 7 is a partial schematic and a partial block diagram of an example of the signal processor 124 in which the first phase signal 118 is compared to the combination of the second phase signal 120 and the third phase signal 122. The signal processor 124 in FIG. 7 includes a rectifier 702. The rectifier 702 (one example of a “first rectifier”) generates a first rectified signal Vrec1 by rectifying the first phase signal 118 which is received at a first terminal 704 of the signal processor 124. The rectifier 702 includes a first pair of switches 706 that rout the first phase signal 118 to a first node 708 or a second node 710 based on the crossing signal 320. For example, the first pair of switches 706 may route the first phase signal 118 to the first node 708 when the crossing signal 320 indicates a first crossing of the signals at the first terminal LC1 and the second terminal LC2 of the resonant LC oscillator 312, and then route the first phase signal 118 to the second node 710 when the crossing signal 320 indicates a second crossing of the signals at the first terminal LC1 and the second terminal LC2 of the resonant LC oscillator 312. The rectifier 702 receives the crossing signal 320 from a control terminal 712 of the signal processor 124 that is coupled to the driver circuit 115.

The rectifier 702 also generates a second rectified signal Vrec2 by rectifying the second phase signal 120 which is received at a second terminal 714 of the signal processor 124. The rectifier 702 also generates a third rectified signal Vrec3 by rectifying the third phase signal 122 which is received at a third terminal 716 of the signal processor 124. The rectifier 702 includes a second pair of switches 718 that rout the second phase signal 120 to the first node 708 or the second node 710 based on the crossing signal 320. The rectifier 702 also includes a third pair of switches 720 that rout the third phase signal 122 to the first node 708 or the second node 710 based on the crossing signal 320. In particular, the second pair of switches 718 and the third pair of switches 720 rout both the second phase signal 120 and the third phase signal 122 to the node opposite the one which the first phase signal 118 is currently routed to.

The signal processor 124 in FIG. 7 includes an integrator 722 configured to generate a first integrated signal Vint1 by integrating the first rectified signal Vrec1. The integrator 722 (one example of a “first integrator”) is also configured to generate a second integrated signal Vint2 by integrating a combination of the second rectified signal Vrec2 and the third rectified signal Vrec3. The integrator 722 in FIG. 7 includes an operational transconductance amplifier 724, a first capacitor 726, a second capacitor 728, a first pair of resistors 730, a second pair of resistors 732, and a third pair of resistors 734. The first capacitor 726 is coupled between a first output of the operational transconductance amplifier 724 and the first node 708. The second capacitor 728 is coupled between a second output of the operational transconductance amplifier 724 and the second node 710. One of the first pair of resistors 730 is coupled in series between one of the first pair of switches 706 and the first node 708. The other of the first pair of resistors 730 is coupled in series between the other of the first pair of switches 706 and the second node 710. One of the second pair of resistors 732 is coupled in series between one of the second pair of switches 718 and the first node 708. The other of the second pair of resistors 732 is coupled in series between the other of the second pair of switches 718 and the second node 710. One of the third pair of resistors 734 is coupled in series between one of the third pair of switches 720 and the first node 708. The other of the third pair of resistors 734 is coupled in series between the other of the third pair of switches 720 and the second node 710. The non-inverting input of the operational transconductance amplifier 724 is coupled to the first node 708. The inverting input of the operational transconductance amplifier 724 is coupled to the second node 710. The second rectified signal Vrec2 and the third rectified signal Vrec3 are combined (or added) at the second node 710. The operational transconductance amplifier 724 generates and outputs the first integrated signal Vint1 on one of its two outputs. The operational transconductance amplifier 724 generates and outputs the second integrated signal Vint2 on the other of its two outputs.

The signal processor 124 in FIG. 7 includes a comparator 736 configured to generate a comparison signal Vcomp by comparing the first integrated signal Vint1 and the second integrated signal Vint2 generated by the integrator 722. The comparison signal Vcomp indicates whether the first phase signal 118 is greater than or less than the combination of the second phase signal 120 and the third phase signal 122. For example, the comparison signal Vcomp may be a first value (e.g., a positive value) when the first phase signal 118 is greater than the combination of the second phase signal 120 and the third phase signal 122, and the comparison signal Vcomp may be a second value (e.g., a negative value) when the first phase signal 118 is less than the combination of the second phase signal 120 and the third phase signal 122.

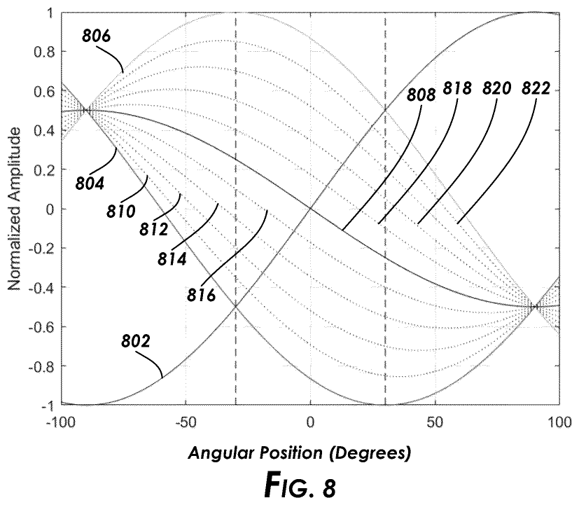

FIG. 8 illustrates plots of examples of waveforms 802, 804, and 806 of the first phase signal 118, the second phase signal 120, and the third phase signal 122, respectively, for different angular positions of the sensor 102. FIG. 8 also illustrates plots of examples of waveforms 808, 810, 812, 814, 816, 816, 818, 820, and 822 of different combinations of the second phase signal 120 and the third phase signal 122. Waveform 808 represents the combination of the second phase signal 120 and the third phase signal 122 when the phase signals are equally weighted. Waveforms 810, 812, 814, 816, 816, 818, 820, and 822 represent the combinations of the second phase signal 120 and the third phase signal 122 when the phase signals are unequally weighted. As illustrated in FIG. 8, the crossing points between waveform 802 and each of the waveforms 804 through 822 are equally distributed across a range of sixty degrees. With the nine different combinations of the second phase signal 120 and the third phase signal 122 illustrated in FIG. 8, detecting the crossing between the waveform 802 and one of the waveform 808 through 822 results in detecting a measuring angular position of the sensor 102 that is within six degrees of the actual angular position of the sensor 102.

Returning to FIG. 7, the comparison signal Vcomp generated by the comparator 736 is received by a calculation circuit 738 of the signal processor 124. The calculation circuit 738 is configured to generate the wake-up signal 126 based on the comparison signal Vcomp. For example, when the default angular position of the sensor 102 is 0°, the combination of the second phase signal 120 and the third phase signal 122 can be set to detect crossings at 6°. Thus, when the sensor 102 rotates away from the default angular position by more than six degrees, the calculation circuit 738 detects a change in polarity of the comparison signal Vcomp and can pulse the wake-up signal 126.

The signal processor 124 illustrated in FIG. 7 includes a first low-pass filter 740, a second low-pass filter 742, and a third low-pass filter 744 for EMC filtering prior to rectification. In some implementations, the first low-pass filter 740, the second low-pass filter 742, and the third low-pass filter 744 include components similar to the ones described above for the first low-pass filter 544 in FIG. 5. In some implementations, the first low-pass filter 740, the second low-pass filter 742, and the third low-pass filter 744 may be formed by other types of passive low-pass filters.

The specific combination of the second phase signal 120 and the third phase signal 122 is set based on the resistance values of the first pair of resistors 730, the second pair of resistors 732, and the third pair of resistors 734. The resistance values of the second pair of resistors 732 apply a first weighting factor to the second rectified signal Vrec2. The resistance values of the third pair of resistors 734 apply a second weighting factor to the third rectified signal Vrec3. The first and second weighting factors are selected such that their sum is equal to one. For example, when the resistances of the first pair of resistors 730 are both R, the resistances of the second pair of resistors 732 are both 4×R, and the resistances of the third pair of resistors 734 are both (4/3)×R, the combination of the second phase signal 120 and the third phase signal 122 is equal to sum of one-fourth of the second phase signal 120 and three-fourths of the third phase signal 122. The sum of the first weighting factor of one-fourth and the second weighting factor of three-fourths is equal to one.

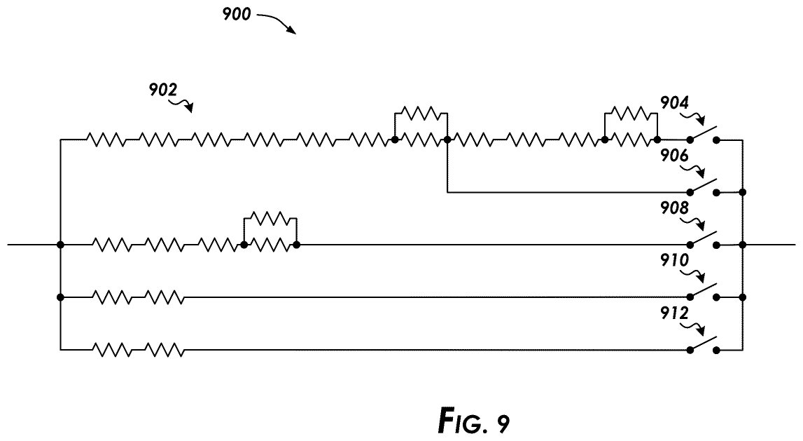

The resistances of the second pair of resistors 732 and the third pair of resistors 734 may be adjustable to select a specific weighted combination of the second phase signal 120 and the third phase signal 122. For example, in some implementations, the second pair of resistors 732 and the third pair of resistors 734 may each be replaced programmable resistors. FIG. 9 is a schematic diagram of an example of a programmable resistor 900. The programmable resistor 900 illustrated in FIG. 9 includes a plurality of resistors 902, a first switch 904, a second switch 906, a third switch 908, a fourth switch 910, and a fifth switch 912. The programmable resistor 900 illustrated in FIG. 9 provides ten tap points for the second phase signal 120 and the third phase signal 122. Programmable resistors with more or less than ten tap points may be used. The overall resistance of the programmable resistor 900 is set based on the positions of the first switch 904, the second switch 906, the third switch 908, the fourth switch 910, and the fifth switch 912. In some implementations, each of the plurality of resistors 902 have the same resistance (e.g., 15 KΩ).

The number of mechanical poles in the sensor 102 can be increased to raise the resolution of angular position detection for wake-up applications. For example, with twelve poles, thirty degrees of mechanical rotation can map to three-hundred and sixty degrees of electrical rotation. Thus, comparing the first phase signal 118 to a combination of the second phase signal 120 and the third phase signal 122 for a sensor with twelve poles can provide 0.5° working units of resolution.

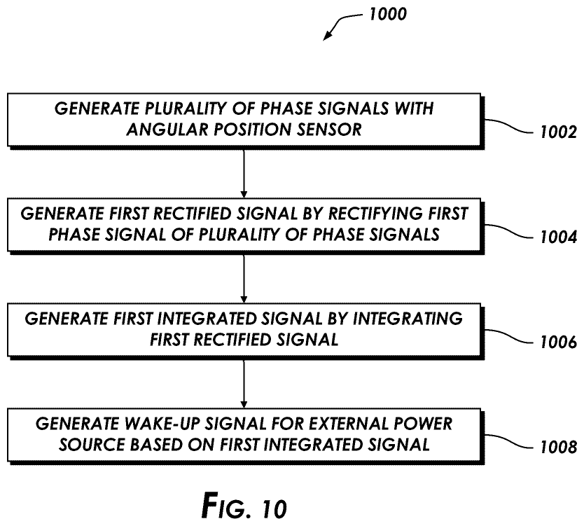

FIG. 10 is a flow diagram of an example of a wake-up method 1000 for an external power source 101. For simplicity of explanation, the wake-up method 1000 is depicted in FIG. 10 and described as a series of operations. However, the operations can occur in various orders and/or concurrently, and/or with other operations not presented and described herein. At block 1002, a plurality of phase signals is generated by an angular position sensor. For example, sensor 102 may generate a first phase signal 118, a second phase signal 120, and a third phase signal 122. At block 1004, a first rectified signal Vrec1 is generated by rectifying a first phase signal 118 of the plurality of phase signals. For example, the first rectified signal Vrec1 is generated by the first rectifier 504 in FIG. 5, the third rectifier 536 in FIG. 6, or the rectifier 702 in FIG. 7 as described above. At block 1006, a first integrated signal Vint1 is generated by integrating the first rectified signal Vrec1. For example, the first integrated signal Vint1 is generated by the first integrator 512 in FIG. 5, the third integrator 538 in FIG. 6, or the integrator 722 in FIG. 7 as described above. At block 1008, a wake-up signal 126 for the external power source 101 is generated based on the first integrated signal Vint1. For example, the calculation circuit 526 in FIG. 5 can pulse the wake-up signal 126 when the comparison signal Vcomp indicates that the first integrated signal Vint1 is greater than the reference voltage Vref. As a further example, the calculation circuit 526 in FIG. 6 can pulse the wake-up signal 126 when the first comparison signal Vcomp1 indicates that the first integrated signal Vint1 is greater than the second integrated signal Vint2. As a further example, the calculation circuit 738 in FIG. 7 can pulse the wake-up signal 126 when the comparison signal Vcomp indicates that the first integrated signal Vint1 is greater than the second integrated signal Vint2.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. A wake-up system for an external power source, comprising:
a rotatable sensor configured to generate a plurality of phase signals; and
an interface circuit configured to:
generate a first rectified signal by rectifying a first phase signal of the plurality of phase signals,
generate a first integrated signal by integrating the first rectified signal, and
generate a wake-up signal for the external power source based on the first integrated signal.

2. The system of claim 1, wherein, to generate the wake-up signal based on the first integrated signal, the interface circuit is further configured to:
generate a comparison signal by comparing the first integrated signal and a reference voltage, and
pulse the wake-up signal when the comparison signal indicates that the first integrated signal is greater than the reference voltage.

3. The system of claim 1, wherein the interface circuit is further configured to:
generate a second rectified signal by rectifying a second phase signal of the plurality of phase signals,
generate a second integrated signal by integrating the second rectified signal, and
generate a comparison signal by comparing the first integrated signal and the second integrated signal,
wherein, to generate the wake-up signal based on the first integrated signal, the interface circuit is further configured to pulse the wake-up signal when the comparison signal indicates that the first integrated signal is greater than the second integrated signal.

4. The system of claim 1, wherein the interface circuit is further configured to:
generate a second rectified signal by rectifying a second phase signal of the plurality of phase signals,
generate a third rectified signal by rectifying a third phase signal of the plurality of phase signals,
generate a combined signal by adding the second rectified signal and the third rectified signal,
generate a second integrated signal by integrating the combined signal, and
generate a comparison signal by comparing the first integrated signal and the second integrated signal, and
wherein, to generate the wake-up signal based on the first integrated signal, the interface circuit is further configured to pulse the wake-up signal when the comparison signal indicates that the first integrated signal is greater than the second integrated signal.

5. The system of claim 4, wherein, to generate the combined signal by adding the second rectified signal and the third rectified signal, the interface circuit is further configured to:
apply a first weighting factor to the second rectified signal, and
apply a second weighting factor to the third rectified signal,
wherein a sum of the first weighting factor and the second weighting factor is equal to one.

6. The system of claim 1, wherein the interface circuit is further configured to:
generate a second rectified signal by rectifying a second phase signal of the plurality of phase signals,
generate a second integrated signal by integrating the second rectified signal,
generate a third rectified signal by rectifying a third phase signal of the plurality of phase signals,
generate a third integrated signal by integrating the third rectified signal,
generate a first comparison signal by comparing the first integrated signal and the second integrated signal,
generate a second comparison signal by comparing the second integrated signal and the third integrated signal,
generate a third comparison signal by comparing the first integrated signal and the third integrated signal, and
generate a turn count for the sensor based on the first comparison signal, the second comparison signal, and the third comparison signal.

7. A wake-up method for an external power source, the method comprising:
generating, with an angular position sensor, a plurality of phase signals;
generating a first rectified signal by rectifying a first phase signal of the plurality of phase signals;
generating a first integrated signal by integrating the first rectified signal; and
generating a wake-up signal for the external power source based on the first integrated signal.

8. The method of claim 7, wherein generating the wake-up signal based on the first integrated signal further includes:
generating a comparison signal by comparing the first integrated signal and a reference voltage, and
pulsing the wake-up signal when the comparison signal indicates that the first integrated signal is greater than the reference voltage.

9. The method of claim 7, further comprising:
generating a second rectified signal by rectifying a second phase signal of the plurality of phase signals;
generating a second integrated signal by integrating the second rectified signal; and
generating a comparison signal by comparing the first integrated signal and the second integrated signal,
wherein generating the wake-up signal based on the first integrated signal further includes pulsing the wake-up signal when the comparison signal indicates that the first integrated signal is greater than the second integrated signal.

10. The method of claim 7, further comprising:
generating a second rectified signal by rectifying a second phase signal of the plurality of phase signals;
generating a third rectified signal by rectifying a third phase signal of the plurality of phase signals;
generating a combined signal by adding the second rectified signal and the third rectified signal;
generating a second integrated signal by integrating the combined signal; and
generating a comparison signal by comparing the first integrated signal and the second integrated signal,
wherein generating the wake-up signal based on the first integrated signal further includes pulsing the wake-up signal when the comparison signal indicates that the first integrated signal is greater than the second integrated signal.

11. The method of claim 7, further comprising:
generating a second rectified signal by rectifying a second phase signal of the plurality of phase signals;
generating a second integrated signal by integrating the second rectified signal;
generating a third rectified signal by rectifying a third phase signal of the plurality of phase signals;
generating a third integrated signal by integrating the third rectified signal;
generating a first comparison signal by comparing the first integrated signal and the second integrated signal;
generating a second comparison signal by comparing the second integrated signal and the third integrated signal;
generate a third comparison signal by comparing the first integrated signal and the third integrated signal; and
generating a turn count for the angular position sensor based on the first comparison signal, the second comparison signal, and the third comparison signal.

12. An interface circuit for an angular position sensor, comprising:
a driver circuit configured to drive the angular position sensor to generate a plurality of phase signals; and
a signal processor including:
a first terminal configured to receive a first phase signal of the plurality of phase signals,
a first rectifier configured to generate a first rectified signal using the first phase signal,
a first integrator configured to generate a first integrated signal using the first rectified signal, and
a calculation circuit configured to generate a wake-up signal for an external power source based on the first integrated signal.

13. The interface circuit of claim 12, wherein the signal processor further includes a comparator configured to generate a comparison signal by comparing the first integrated signal and a reference voltage,
wherein, to generate the wake-up signal based on the first integrated signal, the calculation circuit is further configured to pulse the wake-up signal when the comparison signal indicates that the first integrated signal is greater than the reference voltage.

14. The interface circuit of claim 12, wherein the signal processor further includes:
a second terminal configured to receive a second phase signal of the plurality of phase signals,
a second rectifier configured to generate a second rectified signal using the second phase signal,
a second integrator configured to generate a second integrated signal by integrating the second rectified signal, and
a comparator configured to generate a comparison signal by comparing the first integrated signal and the second integrated signal,
wherein, to generate the wake-up signal based on the first integrated signal, the calculation circuit is further configured to pulse the wake-up signal when the comparison signal indicates that the first integrated signal is greater than the second integrated signal.

15. The interface circuit of claim 12, wherein the signal processor further includes:
a second terminal configured to receive a second phase signal of the plurality of phase signals,
a third terminal configured to receive a third phase signal of the plurality of phase signals, and
a comparator,
wherein the first rectifier is further configured to configured to:
generate a second rectified signal using the second phase signal, and
generate a third rectified signal using the third phase signal,
wherein the first integrator is further configured to:
generate a combined signal by adding the second rectified signal and the third rectified signal, and
generate a second integrated signal by integrating the combined signal,
wherein the comparator is configured to generate a comparison signal by comparing the first integrated signal and the second integrated signal,
wherein, to generate the wake-up signal based on the first integrated signal, the calculation circuit is further configured to pulse the wake-up signal when the comparison signal indicates that the first integrated signal is greater than the second integrated signal.

16. The interface circuit of claim 15, wherein the first integrator includes:
a first resistor configured to apply a first weighting factor to the second rectified signal, and
a second resistor configured to apply a second weighting factor to the third rectified signal,
wherein a sum of the first weighting factor and the second weighting factor is equal to one.

17. The interface circuit of claim 16, wherein the first resistor and the second resistor are programmable resistors.

18. The interface circuit of claim 12, wherein the signal processor further includes:
a second terminal configured to receive a second phase signal of the plurality of phase signals,
a second rectifier configured to generate a second rectified signal using the second phase signal,
a second integrator configured to generate a second integrated signal by integrating the second rectified signal,
a third terminal configured to receive a third phase signal of the plurality of phase signals,
a third rectifier configured to generate a third rectified signal using the third phase signal,
a third integrator configured to generate a third integrated signal by integrating the third rectified signal,
a first comparator configured to generate a first comparison signal by comparing the first integrated signal and the second integrated signal,
a second comparator configured to generate a second comparison signal by comparing the second integrated signal and the third integrated signal, and
a third comparator configured to generate a third comparison signal by comparing the first integrated signal and the third integrated signal,
wherein the calculation circuit is further configured to generate a turn count for the angular position sensor based on the first comparison signal, the second comparison signal, and the third comparison signal.

19. The interface circuit of claim 12, wherein the driver circuit includes:
a tank capacitor,
a pre-charge circuit configured to charge the tank capacitor,
a resonant LC oscillator,
a pulse generator configured to generate an impulse signal,
a first transistor configured to couple a first terminal of the resonant LC oscillator to the tank capacitor responsive to the impulse signal, and
a second transistor configured to couple a second terminal of the resonant LC oscillator to a reference terminal responsive to the impulse signal,
wherein the resonant LC oscillator is configured to generate an excitation signal for driving the angular position sensor in response to the first terminal being coupled to the tank capacitor and the second terminal being coupled to the reference terminal.

20. The interface circuit of claim 19, wherein the driver circuit further includes a phase comparator configured to generate a crossing signal based on the excitation signal, wherein the first rectifier is further configured to generate the first rectified signal using the crossing signal.
